(19) United States
(12) Patent Application Publication
(10) Pub. No.: US 2013/0155363 A1
(43) Pub. Date: Jun. 20, 2013

(54) Array Substrate, LCD and Manufacturing Method of Array Substrate

(71) Applicants: Chiayu Lee, Shenzhen (CN); ShyhFeng Chen, Shenzhen (CN); Zui Wang, Shenzhen (CN)

(72) Inventors: Chiayu Lee, Shenzhen (CN); ShyhFeng Chen, Shenzhen (CN); Zui Wang, Shenzhen (CN)

(21) Appl. No.: 13/380,226

(22) PCT Filed: Dec. 21, 2011
(86) PCT No.: PCT/CN2011/084364

§ 371 Date: Dec. 22, 2011

(30) Foreign Application Priority Data
Dec. 14, 2011 (CN) 201110416371.4

(51) Int. Cl. G02F 1/1333; H01L 33/08

(52) U.S. Cl. 349/138; 257/88; 438/30; 257/E33.053

(57) ABSTRACT

The present invention discloses an array substrate, a liquid crystal display (LCD) and a manufacturing method of the array substrate, wherein, the array substrate comprises insulation layers and an electrode layer densely covered with many pixel electrodes, and has many electric field changing areas; the insulation layers in these areas are not as thick as those in other areas, and the pixel electrodes in the electric field changing areas and in other areas can be conducted. In the present invention, due to the electric field changing areas, the electric field intensities on the surface of the electric field changing areas and on the surface of the electrodes are inconsistent when electrical power is applied, causing the inclination of the power line near these areas, so liquid crystal molecules can deflect in different special directions around these areas, which can expand the display angle. The electric field changing areas can function as electrodes, so these areas still have stronger electric field, which can reduce the number of vertical liquid crystal molecules and the size of dark spots, so as to enhance brightness and wide-angle display effect.

### TECHNICAL FIELD

The present invention relates to the field of liquid crystal display, in particular to array substrate, LCD and manufacturing method of the array substrate.

### BACKGROUND

Liquid crystal molecules of VA (Vertical Alignment Mode) liquid crystal display widely used in daily life are arranged directionally perpendicular to the array substrate and are axially symmetrical when electrical power is cut, and backlight cannot pass through the liquid crystal molecules, so the liquid crystal molecules can deflect in the electric field plane in the same deflecting direction when the electric field acts, which causes contrast reduction or gray level inversion of the display viewed from different points of view. To improve the wide-angle display effect of the VA liquid crystal, the American patent U.S. Pat. No. 6,822,715(B2) proposes an improvement scheme in pixel electrode design. As shown in FIG. 1, several hole openings 24a are made on the pixel electrodes and are arranged in certain geometric shape; when the electric field is applied between electrodes of the upper plate and the lower plate, the liquid crystal molecules deflect in different special directions between the hole openings 24a, which can improve wide-angle display effect.

This scheme has the disadvantages that the hole openings 24a cut off the electrical power directly, so the openings 24a cannot function as electrodes; when the upper plate and the lower plate apply voltage, the electric field in the center of the above openings 24a hardly act, so the liquid crystal molecules are basically perpendicular to the array substrate, causing dark spots shown in FIG. 2, which can reduce brightness and affect the display quality. Furthermore, the size of each hole opening has an obvious influence on the liquid crystal display effect. Therefore, the size of the hole opening must be accurately controlled within a small range. Slight deviation will have an obvious influence on the liquid crystal display effect. The processing accuracy is required to be high.

### SUMMARY

The first aim of the present invention is to provide an array substrate of a LCD which can improve the wide-angle display effect of VA liquid crystal and display no dark spots in pixel electrodes.

The purpose of the present invention is achieved by the following technical schemes.

An array substrate comprises insulation layers and an electrode layer densely covered with many pixel electrodes and has many electric field changing areas; the insulation layers in these areas are not as thick as those in other areas, and the pixel electrodes in the electric field changing areas and in other areas can be conducted.

Preferably, the insulation layer of the array substrate is a first insulation layer arranged at the bottom of the electrode layer; the first insulation layer has many depressed areas, the electrode layer depresses in the depressed areas, and these depressed areas are the electric field changing areas. This is the first embodiment.

Preferably, the array substrate comprises a first insulation layer arranged at the bottom of the electrode layer, and a second insulation layer covering the electrode layer, and the second insulation layer has many depressed areas which are the electric field changing areas. This is the second embodiment.

Preferably, the insulation layer of the array substrate is a first insulation layer arranged at the bottom of the electrode layer; the first insulation layer has many raised areas, the electrode layer raises in the raised areas, and these raised areas are the electric field changing areas. This is the third embodiment.

Preferably, the array substrate comprises a first insulation layer arranged at the bottom of the electrode layer, and a second insulation layer covering the electrode layer, and the second insulation layer has many raised areas which are the electric field changing areas. This is the fourth embodiment.

The second aim of the present invention is to provide a LCD which can improve the wide-angle display effect of VA liquid crystal and display no dark spots in pixel electrodes. The LCD comprises said array substrate.

The third aim of the present invention is to provide a manufacturing method of the array substrate of a LCD which can improve the wide-angle display effect of VA liquid crystal and display no dark spots in pixel electrodes, comprising the following steps:

A: Cover a first transparent substrate with the first insulation layer by the conventional method;

B: Etch the first insulation layer to make the thickness of the first insulation layer different from the thickness of insulation layers in other areas so as to form electric field changing areas;

C: Make pixel electrodes and a first alignment film successively on the first insulation layer by the conventional method;

The manufacturing method of the array substrate of a LCD also can comprise the following steps:

A: Cover the first transparent substrate with the first insulation layer and the pixel electrodes successively by the conventional method;

B: Cover the pixel electrodes with the second insulation layer, and etch the second insulation layer to make the thickness of the second insulation layer different from the thickness of insulation layers in other areas so as to form electric field changing areas;

C: Cover the second insulation layer with the first alignment film.

In the present invention, due to the electric field changing areas, the distance between the pixel electrodes and counter electrodes on the surface of the electric field changing areas is different from that in other areas and the electric field intensities on the surface of the electric field changing areas and on the surface of the electrodes are inconsistent when electrical power is applied, causing the inclination of the power line near these areas, so liquid crystal molecules can deflect in different special directions around these electric field changing areas, which can increase the display angle. The electric field changing areas can function as electrodes, so these areas still have strong electric field, which can reduce the number of vertical liquid crystal molecules and the size of dark spots, so as to enhance brightness and improve wide-angle display effect. Furthermore, for the hole opening, because the electrodes still act in the electric field changing areas, the range of the electric field changing areas can be more flexible, and the range of the electric field changing areas can be adjusted in accordance with the specific display condition, the controllable degree becomes preferable.

### DESCRIPTION OF FIGURES

FIG. 1 is the diagram of the pixel electrode in the prior art.

FIG. 2 is the effect picture of the pixel electrode under the polarized light microscope in orthogonal polarization state in the prior art.

FIG. 3 is the structural diagram of the first embodiment of the present invention;

FIG. 4 is the structural diagram of the second embodiment of the present invention;

FIG. 5 is the structural diagram of the third embodiment of the present invention;

FIG. 6 is the structural diagram of the fourth embodiment of the present invention;

FIG. 7 is the diagram of the pixel electrode in the first embodiment to the fourth embodiment of the present invention;

FIG. 8 is the effect picture of the pixel electrode under the polarized light microscope in orthogonal polarization state in the first embodiment to the fourth embodiment of the present invention.

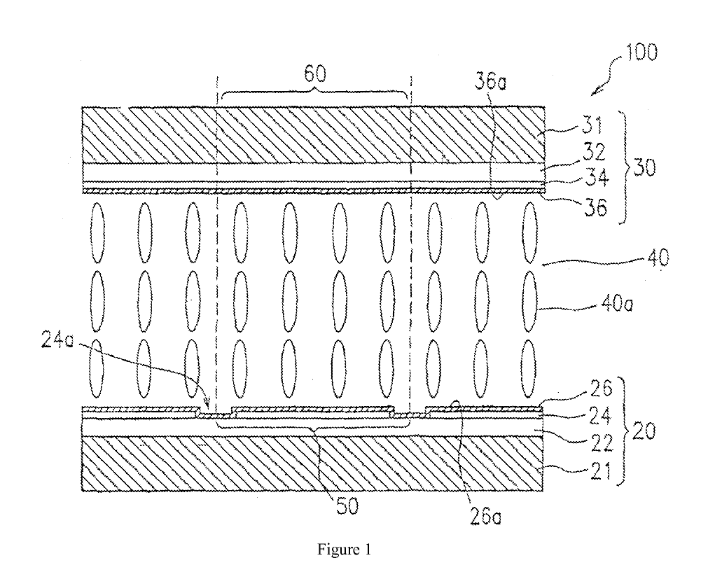

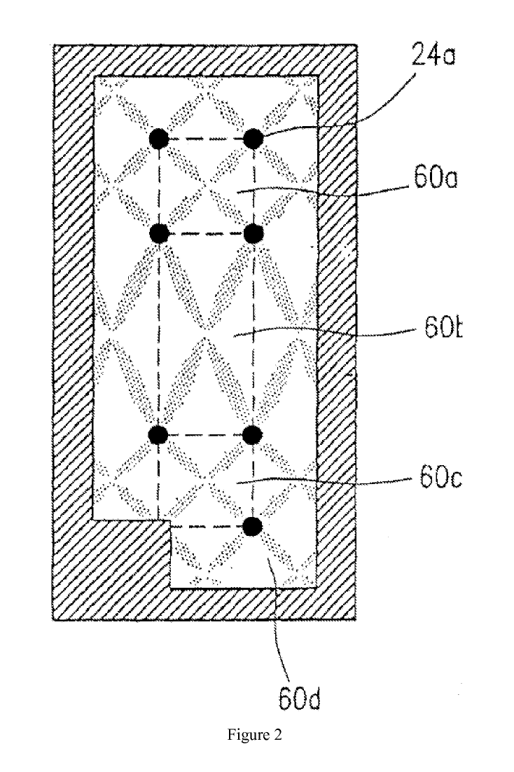

Wherein: 1. color filter substrate, 11. second transparent substrate, 12. color filter plate, 13. counter electrode, 14. second alignment film, 2. array substrate, 21. first transparent substrate, 22. first insulation layer, 23. pixel electrode, 24. first alignment film, 25. second insulation layer, 3. liquid crystal molecule, 4. electric field changing area, 51˜53. sub-pixel area, 6. thin film transistor, 61. grid scanning line, 62. data scanning line.

### DETAILED DESCRIPTION

A LCD comprises an array substrate 2 and a color filter substrate 1, wherein said array substrate has many thin film transistors, each of which corresponds to one pixel electrode. The color filter substrate 1 has counter electrodes corresponding to the pixel electrodes to produce electric field; liquid crystal molecules are filled between the pixel electrodes and the counter electrodes; the array substrate has many electric field changing areas; the insulation layers in these areas are not as thick as those in other areas, and the pixel electrodes in the electric field changing areas and in other areas can be conducted. Due to the electric field changing areas, the electric field intensities on the surface of the electric field changing areas and on the surface of the electrodes are inconsistent when electrical power is applied, causing the inclination of the power line near these areas, so liquid crystal molecules can deflect in different special directions around these areas, which can expand the display angle. The electric field changing areas can function as electrodes, so these areas still have strong electric field, which can reduce the number of vertical liquid crystal molecules and the size of dark spots, so as to enhance brightness and improve wide-angle display effect.

The present invention is further described by figures and the preferred embodiments as follows.

### Embodiment 1

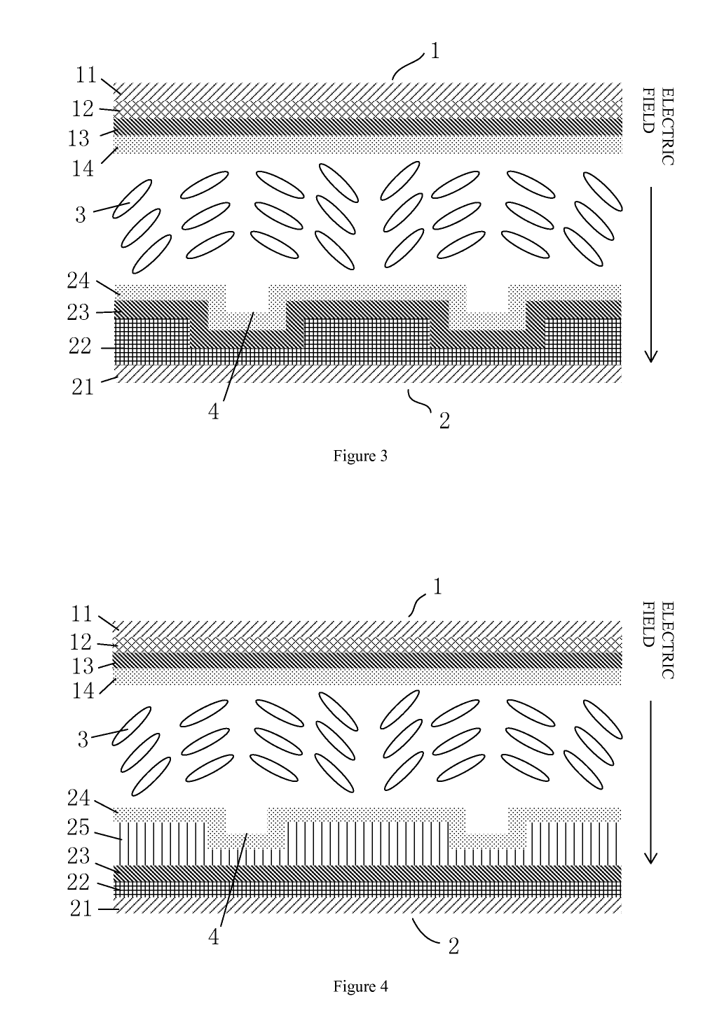

As shown in FIG. 3, the array substrate 2 comprises a first transparent substrate 21, a first insulation layer 22 covering the first transparent substrate 21, an electrode layer covering the first insulation layer 22 and densely covered with many pixel electrodes 23, and a first alignment film 24 covering the pixel electrodes 23; the color filter substrate 1 comprises a second transparent substrate 11, a color filter plate 12 covering the second transparent substrate 11, counter electrodes 13 covering the color filter plate 12, and a second alignment film 14 covering the counter electrodes 13; the first insulation layer 22 has many depressed areas, the electrode layer and the first alignment film 24 depresses in the depressed areas, and these depressed areas are the electric field changing areas 4; the distance between the pixel electrodes 23 and counter electrodes 13 on the surface of the electric field changing areas 4 is longer than that in other areas; when voltage is applied, due to the depression of the electric field changing areas 4, the electric field of the electric field changing areas 4 is different from that of the surrounding areas, the electric field around the electric field changing areas 4 will incline, the adjacent liquid crystal molecules 3 are arranged radially around the electric field changing areas 4.

The manufacturing method of the array substrate 2 of a LCD comprises the following steps:

A: Cover a first transparent substrate 21 with the first insulation layer 22 by the conventional method;

B: Etch the first insulation layer 22 to make the first insulation layer 22 thinner than the insulation layers in other areas so as to form electric field changing areas 4;

C: Make pixel electrodes 23 and a first alignment film 24 successively on the first insulation layer 22 by the conventional method;

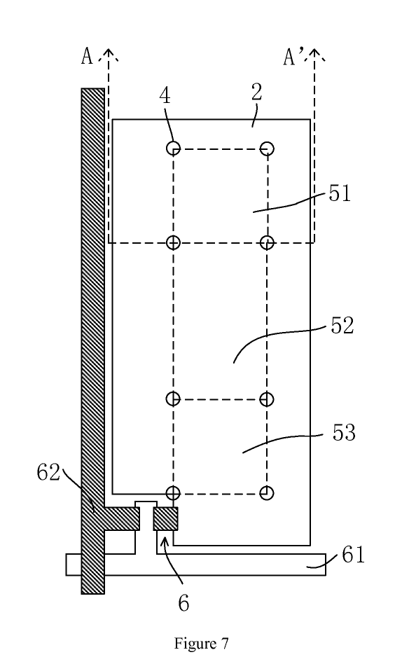

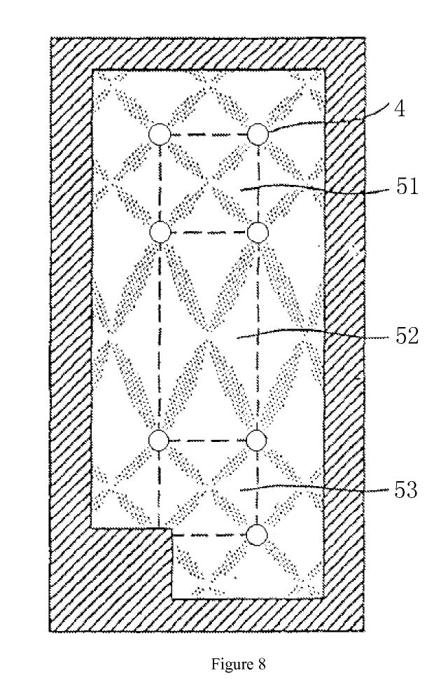

As shown in FIG. 7, each pixel electrode 23 corresponds to one thin film transistor 6, a grid scanning line 61 driving the thin film transistors 6 to be on/off, and a data scanning line 62 driving the pixel electrodes 23. The electric field changing areas 4, in the shape of concave hole or recess, are distributed in the pixel electrodes 23; the center points of the adjacent two electric field changing areas 4 are connected to form square sub-pixel areas 51 and 53, and the area between the two square sub-pixel areas is a rectangular sub-pixel area 52. When electrical power is applied, the liquid crystal molecules 3 near the electric field changing areas 4 are arranged radially and are symmetrical around the center of the square or rectangular sub-pixel area (as shown in FIG. 8), so good visual effect can be obtained from all directions; due to the fourfold-symmetry structure of the square, better symmetrical effect can be obtained, and the effect viewed from different angles is consistent, so the shape of the sub-pixel area is preferably square or other polygon.

The electric field intensities on the surface of the electric field changing areas 4 and on the surface of the electrodes are inconsistent when power is on, causing the inclination of the power line near these areas, so liquid crystal molecules 3 can deflect in different special directions around these areas 4, which can expand the display angle; electrodes still act in the electric field changing areas, so these areas still have stronger electric field, which can reduce the number of vertical liquid crystal molecules 3 and the size of dark spots, so as to enhance brightness and wide-angle display effect. Furthermore, for the hole openings, because the electrodes in the electric field changing areas still act, the range of the electric field changing areas can be more flexible, and the range of the electric field changing areas can be adjusted in accordance with the specific display condition, the controllable degree becomes preferable.

### Embodiment 2

As shown in FIG. 4, the array substrate 2 comprises a first transparent substrate 21, a first insulation layer 22 covering the first transparent substrate 21, an electrode layer covering the first insulation layer 22 and densely covered with many pixel electrodes 23, a second insulation layer 25 additionally covering the electrode layer, and a first alignment film 24 covering the second insulation layer 25; the color filter substrate 1 comprises a second transparent substrate 11, a color filter plate 12 covering the second transparent substrate 11, counter electrodes 13 covering the color filter plate 12, and a second alignment film 14 covering the counter electrodes 13; the second insulation layer 25 has many depressed areas, the first alignment film 24 depresses in the areas, these areas are said electric field changing areas 4, and the distance between the electric field changing areas 4 and the counter electrodes 13 is longer than that in other areas; when voltage is applied, due to the different thickness of the second insulation layer 25, the electric field changing areas 4 are formed at the depression area, the electric field of the electric field changing areas 4 is different from that of the surrounding areas, the electric field of the electric field changing areas 4 will incline, the adjacent liquid crystal molecules 3 are arranged radially around the electric field changing areas 4.

The manufacturing method of the array substrate 2 of a LCD comprises the following steps:

A: Cover the first transparent substrate 21 with the first insulation layer 22 and the pixel electrodes 23 successively by the conventional method;

B: Cover the pixel electrodes 23 with the second insulation layer 25, and etch the second insulation layer 25 to make the second insulation layer 25 thinner than the insulation layers in other areas so as to form electric field changing areas 4;

C: Cover the second insulation layer 25 with the first alignment film 24.

As shown in FIG. 7, each pixel electrode 23 corresponds to one thin film transistor 6, the grid scanning line 61 driving the thin film transistors 6 to be on/off, and the data scanning line 62 driving the pixel electrodes 23. The electric field changing areas 4, in the shape of concave hole or recess, are distributed in the pixel electrodes 23, the center points of the adjacent two electric field changing areas 4 are connected to form square sub-pixel areas 51 and 53, and the area between the two square sub-pixel areas is a rectangular sub-pixel area 52. When electrical power is applied, the liquid crystal molecules 3 near the electric field changing areas 4 are arranged radially and are symmetrical around the center of the square or rectangular sub-pixel area (as shown in FIG. 8), so good visual effect can be obtained from all directions; due to the fourfold-symmetry structure of the square, better symmetrical effect can be obtained, and the effect viewed from different angles is consistent, so the shape of the sub-pixel area is preferably square or other polygon.

The electric field intensities on the surface of the electric field changing areas 4 and on the surface of the electrodes are inconsistent when power on, causing the inclination of the power line near these areas, so liquid crystal molecules 3 can deflect in different special directions around these areas 4, which can expand the display angle; electrodes still act in the electric field changing areas, so these areas still have strong electric field, which can reduce the number of vertical liquid crystal molecules 3 and the size of dark spots, so as to enhance brightness and wide-angle display effect. Furthermore, for the hole openings, because the electrodes in the electric field changing areas still act, the range of the electric field changing areas can be more flexible, and the range of the electric field changing areas can be adjusted in accordance with the specific display condition, the controllable degree becomes preferable.

### Embodiment 3

As shown in FIG. 5, the array substrate 2 comprises a first transparent substrate 21, a first insulation layer 22 covering the first transparent substrate 21, an electrode layer covering the first insulation layer 22 and densely covered with many pixel electrodes 23, and a first alignment film 24 covering the pixel electrodes 23; the color filter substrate 1 comprises a second transparent substrate 11, a color filter plate 12 covering the second transparent substrate 11, counter electrodes 13 covering the color filter plate 12, and a second alignment film 14 covering the counter electrodes 13; the first insulation layer 22 has many raised areas, the electrode layer and the first alignment film 24 raises Outward the raised areas, and these raised areas are the electric field changing areas 4, and; the distance between the pixel electrodes 23 and counter electrodes 13 on the surface of the electric field changing areas 4 is shorter than that in other areas; when voltage is applied, due to the raising of the electric field changing areas 4, the electric field of the electric field changing areas 4 is different from that of the surrounding areas, the electric field of the electric field changing areas 4 will incline, the adjacent liquid crystal molecules 3 are arranged radially around the electric field changing areas.

The manufacturing method of the array substrate 2 of a LCD comprises the following steps:

A: Cover a first transparent substrate 21 with the first insulation layer 22 by the conventional method;

B: Etch the first insulation layer 22 to make the first insulation layer 22 thicker than the insulation layers in other areas so as to form electric field changing areas 4;

C: Make pixel electrodes 23 and a first alignment film 24 successively on the first insulation layer 22 by the conventional method;

As shown in FIG. 7, each pixel electrode 23 corresponds to one thin film transistor 6, the grid scanning line 61 driving the thin film transistors 6 to be on/off, and the data scanning line 62 driving the pixel electrodes 23. The electric field changing areas 4, in the shape of circular boss or square boss, are distributed in the pixel electrodes 23; the center points of the adjacent two electric field changing areas 4 are connected to form square sub-pixel areas 51 and 53, and the area between the two square sub-pixel areas is a rectangular sub-pixel area 52. When electrical power is applied, the liquid crystal molecules 3 near the electric field changing areas 4 are arranged radially and are symmetrical around the center of the square or rectangular sub-pixel area (as shown in FIG. 8), so good visual effect can be obtained from all directions; due to the fourfold-symmetry structure of the square, better symmetrical effect can be obtained, and the effect viewed from different angles is consistent, so the shape of the sub-pixel area is preferably square or other polygon.

The electric field intensities on the surface of the electric field changing areas 4 and on the surface of the electrodes are inconsistent when power on, causing the inclination of the power line near these areas, so liquid crystal molecules 3 can deflect in different special directions around these areas 4, which can expand the display angle; electrodes still act in the electric field changing areas, so these areas still have stronger electric field, which can reduce the number of vertical liquid crystal molecules 3 and the size of dark spots, so as to enhance brightness and wide-angle display effect. Furthermore, for the hole openings, because the electrodes in the electric field changing areas still act, the range of the electric field changing areas can be more flexible, and the range of the electric field changing areas can be adjusted in accordance with the specific display condition, the controllable degree becomes preferable.

### Embodiment 4

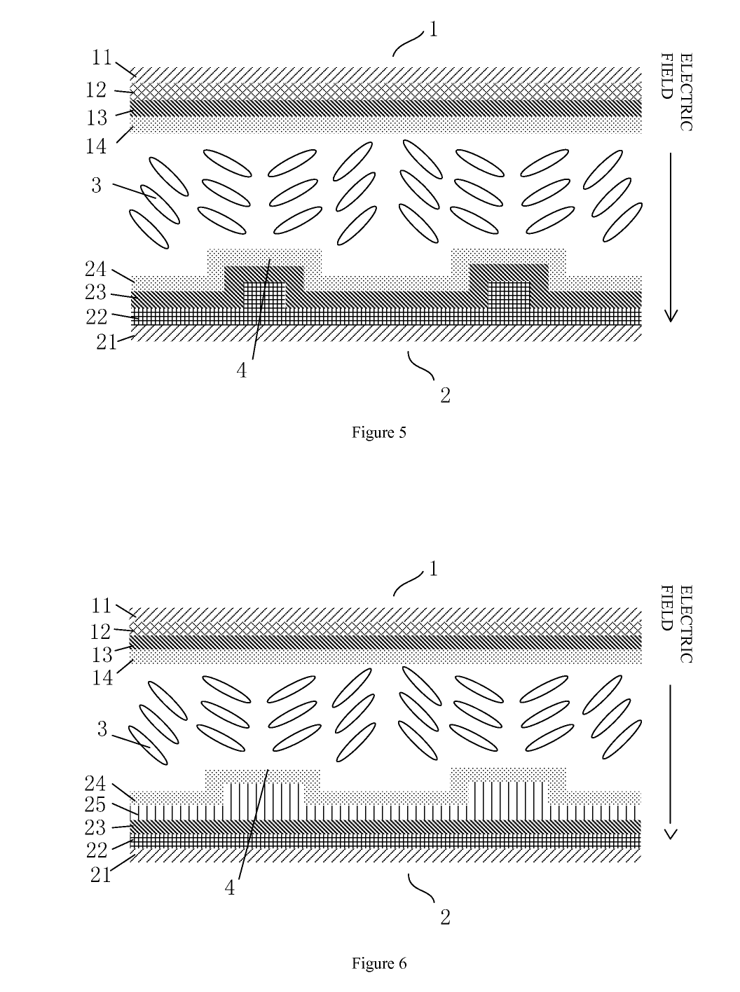

As shown in FIG. 6, the array substrate 2 comprises a first transparent substrate 21, a first insulation layer 22 covering the first transparent substrate 21, an electrode layer covering the first insulation layer 22 and densely covered with many pixel electrodes 23, a second insulation layer 25 additionally covering the electrode layer, and a first alignment film 24 covering the second insulation layer 25; the color filter substrate 1 comprises a second transparent substrate 11, a color filter plate 12 covering the second transparent substrate 11, counter electrodes 13 covering the color filter plate 12, and a second alignment film 14 covering the counter electrodes 13; the second insulation layer 25 has many raised areas, the first alignment film 24 raises in the raised areas, these areas are said electric field changing areas 4, and the distance between the surface of the electric field changing areas 4 and the counter electrodes 13 is shorter than that in other areas; when voltage is applied, due to the different thickness of the second insulation layer 25, the electric field changing areas 4 are formed at the raised areas, the electric field of the electric field changing areas 4 is different from that of the surrounding areas, the electric field of the electric field changing areas 4 will incline, the adjacent liquid crystal molecules 3 are arranged radially around the electric field changing areas 4.

The manufacturing method of the array substrate 2 of a LCD comprises the following steps:

A: Cover the first transparent substrate 21 with the first insulation layer 22 and the pixel electrodes 23 successively by the conventional method;

B: Cover the pixel electrodes 23 with the second insulation layer 25, and etch the second insulation layer 25 to make the second insulation layer 25 thicker than the insulation layers in other areas so as to form electric field changing areas 4;

C: Cover the second insulation layer 25 with the first alignment film 24.

As shown in FIG. 7, each pixel electrode 23 corresponds to one thin film transistor 6, the grid scanning line 61 driving the thin film transistors 6 to be on/off, and the data scanning line 62 driving the pixel electrodes 23. The electric field changing areas 4, in the shape of concave hole or recess, are distributed in the pixel electrodes 23, the center points of the adjacent two electric field changing areas 4 are connected to form square sub-pixel areas 51 and 53, and the area between the two square sub-pixel areas is a rectangular sub-pixel area 52. When electrical power is applied, the liquid crystal molecules 3 near the electric field changing areas 4 are arranged radially and are symmetrical around the center of the square or rectangular sub-pixel area (as shown in FIG. 8), so good visual effect can be obtained from all directions; due to the fourfold-symmetry structure of the square, better symmetrical effect can be obtained, and the effect viewed from different angles is consistent, so the shape of the sub-pixel area is preferably square or other polygon.

When electrical power is applied, the electric field intensities on the surface of the electric field changing areas 4 and on the surface of the electrodes are inconsistent, causing the inclination of the power line near these areas, so liquid crystal molecules can deflect in different special directions around these electric field changing areas 4, which can expand the display angle. The electric field changing areas 4 can function as electrodes, so these areas still have strong electric field, which can reduce the number of vertical liquid crystal molecules 3 and the size of dark spots, so as to enhance brightness and improve wide-angle display effect. Furthermore, for the hole opening, because the electrodes still act in the electric field changing areas, the range of the electric field changing areas can be more flexible, and the range of the electric field changing areas can be adjusted in accordance with the specific display condition, the controllable degree becomes preferable.

The present invention is described in detail in accordance with the above contents with the specific preferred embodiments. However, this invention is not limited to the specific embodiments. For the ordinary technical personnel of the technical field of the present invention, on the premise of keeping the conception of the present invention, the technical personnel can also make simple deductions or replacements, and all of which should be considered to belong to the protection scope of the present invention.

We claim:

1. An array substrate, comprising insulation layers and an electrode layer densely covered with many pixel electrodes, and having many electric field changing areas; the insulation layers in these areas are not as thick as those in other areas, and the pixel electrodes in the electric field changing areas and in other areas can be conducted.

2. The array substrate of claim 1, wherein said insulation layer of the array substrate is a first insulation layer arranged at the bottom of the electrode layer; the first insulation layer has many depressed areas; the electrode layer depresses in the depressed areas, and these depressed areas are the electric field changing areas.

3. The array substrate of claim 1, wherein said array substrate comprises a first insulation layer arranged at the bottom of the electrode layer, and a second insulation layer covering the electrode layer, and the second insulation layer has many depressed areas which are the electric field changing areas.

4. The array substrate of claim 1, wherein said insulation layer of the array substrate is a first insulation layer arranged at the bottom of the electrode layer; the first insulation layer has many raised areas; the electrode layer raises in the raised areas, and these raised areas are the electric field changing areas.

5. The array substrate of claim 1, wherein said array substrate comprises a first insulation layer arranged at the bottom of the electrode layer, and a second insulation layer covering the electrode layer, and the second insulation layer has many raised areas which are the electric field changing areas.

6. A LCD, comprising an array substrate, wherein said array substrate comprises the insulation layers and the electrode layer densely covered with many pixel electrodes and has many electric field changing areas; the insulation layers in these areas are not as thick as those in other areas, and the pixel electrodes in the electric field changing areas and in other areas can be conducted.

7. The LCD of claim 6, wherein said insulation layer of the array substrate is the first insulation layer arranged at the bottom of the electrode layer; the first insulation layer has many depressed areas; the electrode layer depresses in the depressed areas, and these depressed areas are the electric field changing areas.

8. The LCD of claim 6, wherein said array substrate comprises the first insulation layer arranged at the bottom of the electrode layer, and the second insulation layer covering the electrode layer, and the second layer has many depressed areas which are the electric field changing areas.

9. The LCD of claim 6, wherein said insulation layer of the array substrate is the first insulation layer arranged at the bottom of the electrode layer; the first insulation layer has many raised areas; the electrode layer raises in the raised areas, and these raised areas are the electric field changing areas.

10. The LCD of claim 6, wherein said array substrate comprises the first insulation layer arranged at the bottom of the electrode layer, and the second insulation layer covering the electrode layer, and the second insulation layer has many raised areas which are the electric field changing areas.

11. A manufacturing method of an array substrate of a LCD comprises the following steps:
A: cover a first transparent substrate with the first insulation layer by the conventional method;
B: etch the first insulation layer to make the thickness of the first insulation layer different from the thickness of insulation layers in other areas so as to form electric field changing areas;
C: make pixel electrodes and a first alignment film successively on the first insulation layer by the conventional method;

12. A manufacturing method of an array substrate of a LCD comprises the following steps:
A: cover the first transparent substrate with the first insulation layer and the pixel electrodes successively by the conventional method;
B: cover the pixel electrodes with the second insulation layer, and etch the second insulation layer to make the thickness of the second insulation layer different from the thickness of insulation layers in other areas so as to form electric field changing areas;
C: cover the second insulation layer with the first alignment film.
